(19) United States
(12) Patent Application Publication
(10) Pub. No.: US 2007/0173084 A1
(43) Pub. Date: Jul. 26, 2007

(54) BOARD-TO-BOARD CONNECTING STRUCTURE

(75) Inventor: YUAN-PO WANG, Chu-Nan (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: ALTUS TECHNOLOGY INC., Chu-Nan (TW)

(21) Appl. No.: 11/309,754

(22) Filed: Sep. 22, 2006

(30) Foreign Application Priority Data
Jan. 21, 2006 (CN) 200610033257.2

(51) Int. Cl. H05K 1/00

(52) U.S. Cl. 439/77

(57) ABSTRACT

A board-to-board connecting structure (100) includes a flexible circuit board (10) and a substrate (210) fixed to the flexible circuit board (10). The substrate (210) has a plurality of first pads (212) and a plurality of first connecting sheets (214) disposed thereon, and the flexible circuit board has a plurality of second pads (112) and a plurality of second connecting pads (114) disposed thereon. The first pads are fixed to the second pads, and the first connecting sheets are fixed to the second connecting sheets.

### FIELD OF THE INVENTION

The present invention relates generally to board-to-board connecting structures and, more particularly, to a structure for connecting a substrate to a flexible circuit board.

### DESCRIPTION OF RELATED ART

With the development of scientific technology, portable electronic devices for imaging, such as digital cameras and mobile phones with digital camera modules, have all entered widespread use. Typically, portable electronic devices, such as mobile phones, are equipped to create images using a digital camera module mounted on a flexible circuit board. The flexible circuit board electrically connects to a main circuit board of the portable electronic device thus enabling signal transmission between the digital camera module and the main circuit board. The digital camera module normally includes a substrate carrying an image sensor and a plurality of pads located on the substrate thereof. The flexible circuit board on which the digital camera module is mounted includes a mounting area and a plurality of pads in positions corresponding to the pads of the substrate disposed within the mounting area thereof. The pads of the substrate are electrically connected to the corresponding pads of the flexible circuit board by means of surface mounting technology.

Due to needs for smaller and smaller portable electronic devices in size, there is a pressing need for digital camera modules with smaller size. In this case, the mounting area of the flexible circuit board has roughly same size as the substrate. The substrate has a substantially rectangular bottom surface, which connects to the mounting area except at four corners thereof. When an excessive force is applied to one or more corners, the substrate and the digital camera module may become separated from the flexible circuit board. This may result in total malfunction of the digital camera module.

The related art includes two solutions to the above-mentioned problem: one is to add additional reinforcing, like plastic or metal etc. having relative high rigidity beneath the substrate and the flexible circuit board, the other is to add additional adhesive within an area between the substrate and the flexible circuit board. However, each way has its shortcoming as the first method may decrease flexibility of the flexible circuit board and the second method requires another gluing process.

What is needed, therefore, is a board-to-board connecting structure that can overcome the above-mentioned shortcomings.

### SUMMARY OF THE INVENTION

In one embodiment thereof, a board-to-board connecting structure is provided comprising a flexible circuit board and a substrate fixed to the flexible circuit board. The substrate has a plurality of first pads and a plurality of first connecting sheets disposed thereon, and the flexible circuit board has a plurality of second pads and a plurality of second connecting sheets disposed thereon. The first pads are fixed to the second pads, and the first connecting sheets are fixed to the second connecting sheets.

Other advantages and novel features will become more apparent from the following detailed description when taken in conjunction with the accompanying drawings.

### BRIEF DESCRIPTION OF THE DRAWINGS

Many aspects of the board-to-board connecting structure can be better understood with reference to the following drawings. These drawings are not necessarily drawn to scale, the emphasis instead being placed upon clearly illustrating the principles of the present board-to-board. Moreover, in the drawings, like reference numerals designate corresponding parts throughout the several views, in which:

FIG. 1 is an exploded view of a board-to-board connecting structure in a digital camera module in accordance with a preferred embodiment;

FIG. 2 is an isometric view of the digital camera module shown in FIG. 1; and

FIG. 3 is an assembled view of the board-to-board connecting structure shown in FIG. 1.

### DETAILED DESCRIPTION OF PERFERRED EMBODIMENTS

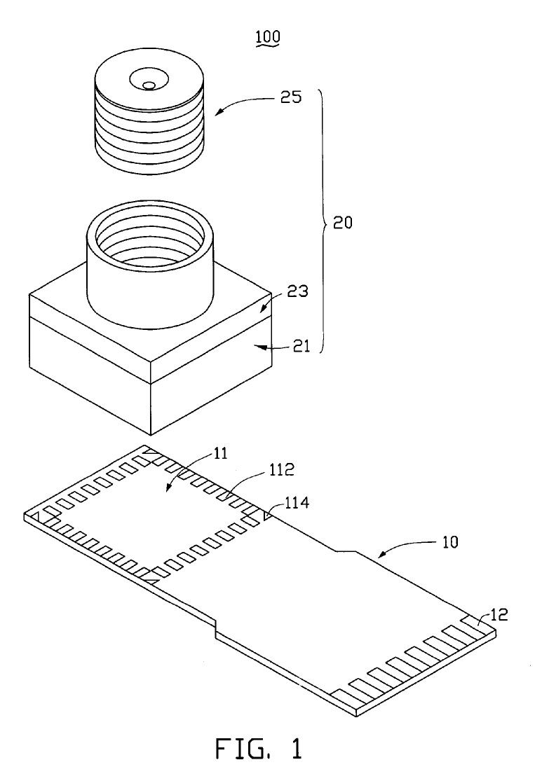

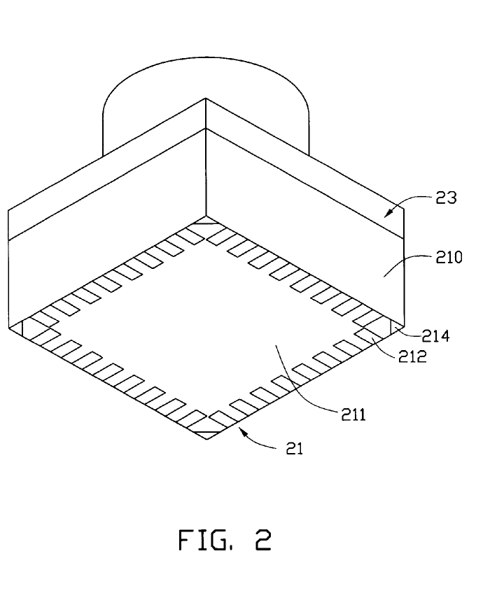

The board-to-board connecting structure is suitable for any portable electronic device, especially portable electronic device for imaging. Referring to FIGS. 1 and 2, the preferred embodiment takes a flexible circuit board 10 connecting to substrate 210 of a digital camera module 20 as an example of a board-to-board connecting structure 100.

Referring to drawings in detail, FIG. 1 shows a flexible circuit board 10 and a digital camera module 20 including an image sensor package 21, a lens barrel 23 and a lens module 25.

Referring also to FIG. 2, the image sensor package 21 includes a substrate 210, and has a plurality of first pads 212 and a plurality of first connecting sheets 214 disposed on the substrate 210 thereof. The first pads 212 transmit the signal from the image sensor package 21. The first connecting sheets 214 connect to the flexible circuit board 10. The substrate 210 has a generally rectangular bottom surface 211. Those first pads 212 can be arranged and distributed on the bottom surface 211 in varying patterns, including dotted and circular patterns etc. Correspondingly, the first connecting sheets 214 can also be arranged and distributed on the bottom surface in varying patterns. For example, when the first pads 212 are arranged and distributed in a middle of the bottom surface 211 in a circular pattern, the first connecting sheets 214 may be disposed around the perimeter of the first pads 212. The first pads 212 are preferably evenly arranged and distributed on the four corner edges of the bottom surface 211. The first connecting sheets 214 are preferably four in number, and are each arranged and distributed at a respective one of four corners formed by the four corner edges of the bottom surface 211.

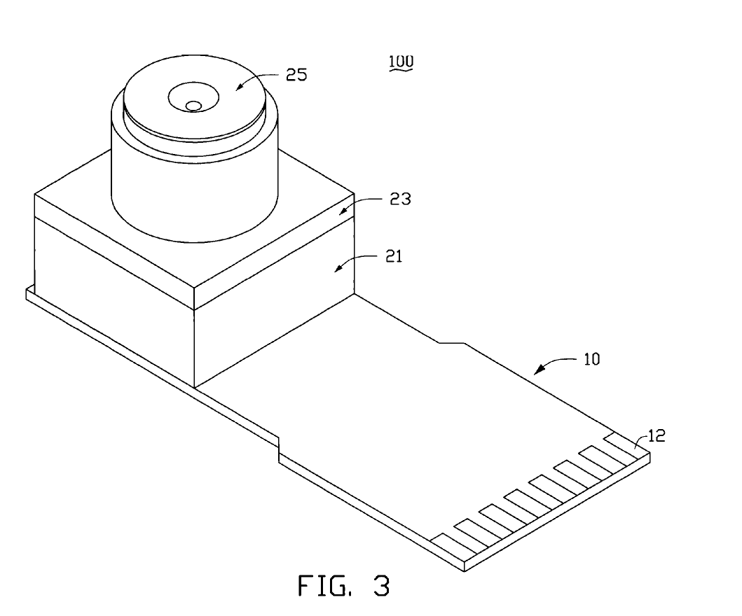

The flexible circuit board 10 shown in FIG. 1 is integrally formed with the digital camera module 20 (shown in FIG. 3). Referring now to FIG. 1, the flexible circuit board 10 has a plurality of second pads 112 and a plurality of second connecting sheets 114 disposed thereon, and also includes an electric connector 12 formed therewith used for electrically connecting to other electronic elements. The second pads 112 are electrically coupled to the electric connector 12 via internal circuitry printed on the flexible circuit board 10. When the flexible circuit board 10 is coupled to the digital camera module 20, the second pads 112 are coupled to the first pads 212, and the second connecting sheets 114 are coupled to the first connecting sheets 214. Preferably, the second pads 112 and the second connecting sheets 114 cooperatively form a roughly rectangular mounting area 11. The second pads 112 are evenly arranged and disposed on each of the four corner edges of the mounting area 11. The second connecting sheets 114 are evenly arranged and disposed on each four corners of the mounting area 11.

Referring also to FIG. 3, FIG. 3 illustrates is an assembled exemplary board-to-board connecting structure 100 that a flexible circuit board 10 connecting to substrate 21 of a digital camera module 20. In assembly, the flexible circuit board 10 is provided with the second pads 112 and the second connecting sheets 114. The second pads 112 and the second connecting sheets 114 are wrapped with solder material such as tin cream. The image sensor package 21 of the digital camera module 20 is disposed on the flexible circuit board 10. The substrate 210 of the image sensor package 21 is in alignment with the mounting area 11 of the flexible circuit board 10, the first pads 212 contact with the second pads 112, and the first connecting sheets 214 contact with the second connecting sheets 114. The image sensor package 21 and the flexible circuit board 10 therewith are welded to form a whole. In this case, the image sensor package 21 is fixed to the flexible circuit board 10, the first pads 212 are coupled to the second pads 112, and the first connecting sheets 214 are coupled to the second connecting sheets 114. A lens barrel 23 and a lens module 25 are provided, and are assembled together with the image sensor package 21 and the flexible circuit board 10 in sequence, thus assembling the board-to-board connecting structure 100.

A main advantage of the board-to-board connecting structure 100 is that the plurality of first connecting sheets 214 in co-operation with the second connecting sheets 114 forms a connecting means that enables a high stability connection to be maintained between the flexible board 10 and the substrate 210, whilst also maintaining the flexibility of the flexible board 10.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A board-to-board connecting structure, comprising:
a flexible circuit board having a plurality of second pads and a plurality of second connecting sheets disposed thereon; and
a substrate having a plurality of first pads and a plurality of first connecting sheets disposed thereon, wherein the first pads of the substrate are correspondingly fixed to the second pads of the flexible circuit board, the first connecting sheets are correspondingly fixed to the second connecting sheets of the flexible circuit board.

2. The board-to-board connecting structure as claimed in claim 1, wherein the flexible circuit board defines a mounting area for mounting the substrate.

3. The board-to-board connecting structure as claimed in claim 2, wherein the plurality of first pads are arranged and disposed on the four corner edges of the bottom surface of the substrate, the plurality of second pads are each arranged and disposed at one of four corner edges of the mounting area.

4. The board-to-board connecting structure as claimed in claim 3, wherein the plurality of first connecting sheets are each arranged and disposed at one of four corners of the bottom surface of the substrate, the plurality of second connecting sheets are each arranged and disposed at one of four corners of the mounting area.

5. The board-to-board connecting structure as claimed in claim 1, wherein each of the first pads is electrically coupled to a respective one of the second pads.

6. The board-to-board connecting structure as claimed in claim 1, wherein the substrate is that of a digital camera module.

7. A board-to-board connecting structure, comprising:
a flexible circuit board having a plurality of second conductive means and a plurality of second connecting means formed therewith; and
a substrate having a plurality of first conductive means and a plurality of first connecting sheets disposed thereon, wherein the first conductive means of the substrate are correspondingly fixed to the second conductive means of the flexible circuit board, the first connecting means are correspondingly fixed to the second connecting means of the flexible circuit board.

8. The board-to-board connecting structure as claimed in claim 7, wherein the first and second conductive means are pads, the first and second connecting means are connecting sheets.

9. The board-to-board connecting structure as claimed in claim 7, wherein the flexible circuit board has a mounting area defined for mounting the substrate, the plurality of first conductive means are arranged and disposed on the four corner edges of the bottom surface of the substrate, the plurality of second conductive means are arranged and disposed at the four corner edges of the mounting area.

10. The board-to-board connecting structure as claimed in claim 7, wherein the flexible circuit board has a mounting area defined for mounting the substrate, the plurality of first connecting means are arranged and disposed on the four corners of the bottom surface of the substrate, the plurality of second connecting means are arranged and disposed at the four corners of the mounting area.

11. A digital camera module comprising:
a lens module;
an image sensor package positioned so as to receive light transmitted from the lens module, the image sensor package including a substrate having a bottom surface, and a plurality of first conductive means and a plurality of first connecting means formed on the bottom surface; and
a flexible circuit board having a top surface, a plurality of second conductive means and a plurality of second connecting means formed on the top surface, the second conductive means being welded to the first conductive means, the second connecting means being welded to the first connecting means.

12. The board-to-board connecting structure as claimed in claim 11, wherein the flexible circuit board has a mounting area defined for mounting the substrate, the plurality of first conductive means are arranged and disposed on the four corner edges of the bottom surface of the substrate, the plurality of second conductive means are arranged and disposed at the four corner edges of the mounting area.

13. The board-to-board connecting structure as claimed in claim 11, wherein the flexible circuit board has a mounting area defined for mounting the substrate, the plurality of first connecting means are arranged and disposed on the four corners of the bottom surface of the substrate, the plurality of second connecting means are arranged and disposed at the four corners of the mounting area.
